(19) United States
(12) Patent Application Publication
(10) Pub. No.: US 2011/0164361 A1
(43) Pub. Date: Jul. 7, 2011

(54) ELECTRONIC APPARATUS

(75) Inventors: Eui Shik YOON, Suwon-si (KR); Se Ki JANG, Hwaseong-si (KR); Jee Youl YUN, Suwon-si (KR)

(73) Assignee: SAMSUNG ELECTRONICS CO., LTD., Suwon-si (KR)

(21) Appl. No.: 12/985,712

(22) Filed: Jan. 6, 2011

(30) Foreign Application Priority Data
Jan. 7, 2010 (KR) 10-2010-1370

(51) Int. Cl. H05K 5/02

(52) U.S. Cl. 361/679.01

(57) ABSTRACT

Disclosed herein is an electronic apparatus including a case having an accessory installation region, a cover to cover the accessory installation region, and a locking member movably mounted to the case and adapted to be caught by the cover. The cover is moved to protrude outward from the accessory installation region as the locking member is moved to unlock the cover, thereby being more easily separated from the case.

### CROSS-REFERENCE TO RELATED APPLICATION

This application claims the benefit of Korean Patent Application No. 2010-0001370, filed on Jan. 7, 2010, in the Korean Intellectual Property Office, the disclosure of which is incorporated herein by reference.

### BACKGROUND

1. Field

Exemplary embodiments relate to an electronic apparatus having an accessory separably installed to a case.

2. Description of the Related Art

Generally, an electronic apparatus is configured in such a manner that a variety of electronic elements is arranged within a case defining an external appearance of the electronic apparatus. Of electronic apparatuses, a portable electronic apparatus, such as a cellular phone or E-book (short for electronic books), has appeared in recent years.

A portable electronic apparatus includes a separable accessory, such as, e.g., a battery for power supply or an external memory card that serves as a storage medium. To install the accessory, a case of the electronic apparatus includes an accessory installation region defined in a surface thereof, to allow the accessory to be placed in the accessory installation region. In addition, a cover is separably fitted to the accessory installation region to cover and hide the accessory installation region after the accessory is placed in the accessory installation region.

### SUMMARY

Therefore, it is an aspect of exemplary embodiments to provide an electronic apparatus to assure more easy separation, i.e., removal, of a cover from an accessory installation region.

Additional aspects of the exemplary embodiments will be set forth in part in the description which follows and, in part, will be obvious from the description, or may be learned by practice of the exemplary embodiments.

In accordance with one aspect of an exemplary embodiment, an electronic apparatus includes a case having an accessory installation region defined in a surface thereof, in which an accessory is separably, i.e., removably, installed, a cover separably coupled to the accessory installation region to cover the accessory installation region, and a locking member mounted in the accessory installation region in a forwardly or rearwardly movable manner and adapted to be moved in a first direction and be caught by one end of the cover, wherein the end of the cover is moved to protrude outward from the accessory installation region as the locking member is moved in a second direction opposite to the first direction.

The cover protruding from the accessory installation region may be moved in the second direction along with the locking member as the locking member is further moved in the second direction.

The electronic apparatus may further include a first guide provided at the locking member, and a second guide provided at the cover and placed on a movement path of the first guide, and the second guide may include a first guide surface inclined with respect to the movement path of the first guide.

The second guide may further include a second guide surface to be caught by the first guide so as to allow the cover to be moved in the second direction along with the locking member.

The accessory installation region may be provided at one end thereof with a pair of first rails on which the locking member is movably mounted, and the locking member may include a knob portion to which external force is applied, and a pair of second rails spaced apart from the knob portion and movably mounted on the first rails.

The locking member may include a first locking portion extending in the first direction and adapted to be caught by the cover, and the cover may include a second locking portion having a locking recess into which the first locking portion is inserted and caught.

The electronic apparatus may further include an elastic member to elastically support the locking member in the second direction opposite to the first direction.

The cover may include a first retention portion protruding from the other end of the cover and adapted to be caught by the accessory installation region, and the accessory installation region may include a first retention hole by which the first retention portion is caught and supported.

The cover may include a second retention portion provided at a position adjacent to either lateral end thereof and adapted to be caught by the accessory installation region, and the accessory installation region may include a second retention hole by which the second retention portion is caught and supported, and a third retention portion protruding inward of the second retention hole to allow the second retention portion to be selectively caught by the third retention portion according to a position of the cover.

The electronic apparatus may further include a battery for power supply, and the accessory installation region may include a battery installation recess having a shape corresponding to the battery to allow the battery to be separably seated therein.

In accordance with another aspect of an exemplary embodiment, an electronic apparatus includes a case having an accessory installation region defined in a surface thereof, in which an accessory is separably installed, a cover separably coupled to the accessory installation region to cover the accessory installation region, a locking member mounted in the accessory installation region in a forwardly or rearwardly movable manner and adapted to be moved in a first direction and be caught by one end of the cover, a first guide provided at the locking member, and a second guide provided at the cover and placed on a movement path of the first guide of the locking member that is adapted to be moved in a second direction opposite to the first direction, wherein the second guide includes a first guide surface inclined with respect to the movement path of the first guide.

### BRIEF DESCRIPTION OF THE DRAWINGS

These and/or other aspects of the exemplary embodiments will become apparent and more readily appreciated from the following description of the exemplary embodiments, taken in conjunction with the accompanying drawings of which:

FIGS. 1 and 2 are exploded perspective views illustrating an electronic apparatus according to an exemplary embodiment;

FIG. 3 is an exploded perspective view illustrating an installation configuration of a locking member included in the electronic apparatus according to the exemplary embodiment;

FIG. 4 is a sectional view illustrating the installation configuration of the locking member included in the electronic apparatus according to the exemplary embodiment; and

FIGS. 5 to 8 are sectional views illustrating operation of the locking member included in the electronic apparatus according to the exemplary embodiment.

### DETAILED DESCRIPTION

Reference will now be made in detail to an electronic apparatus according to an exemplary embodiment, examples of which are illustrated in the accompanying drawings, wherein like reference numerals refer to like elements throughout.

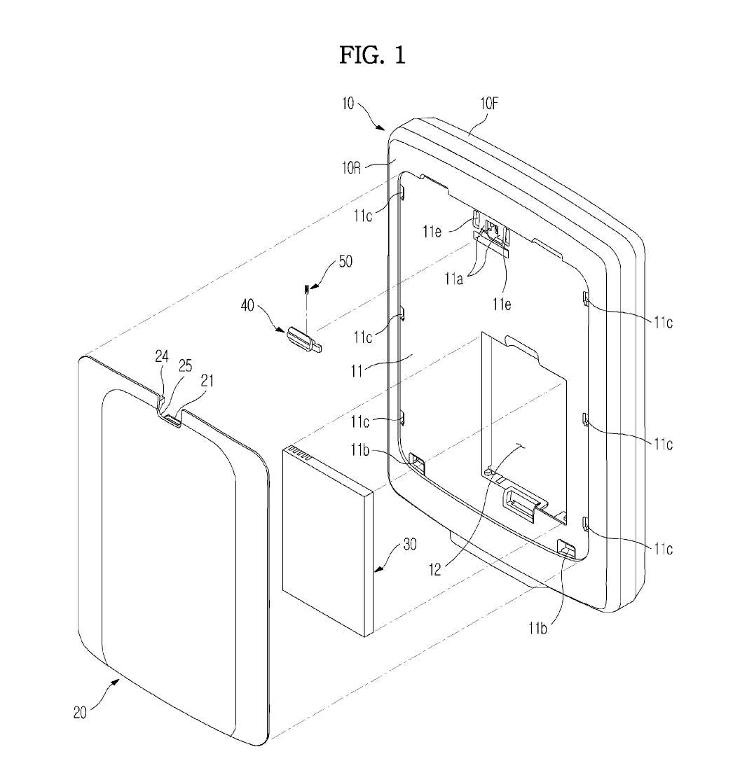

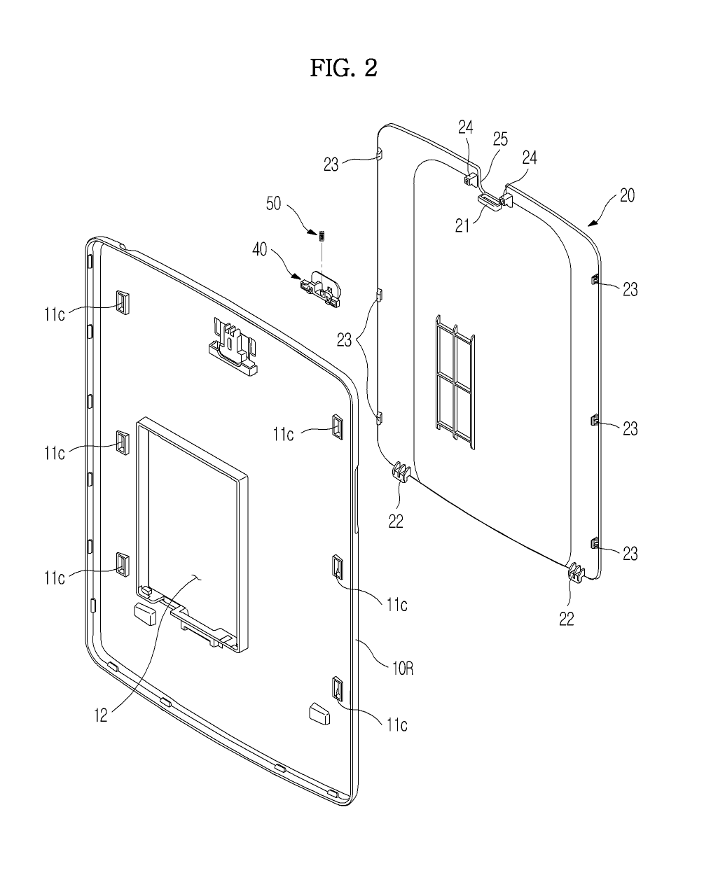

As illustrated in FIGS. 1 and 2, the electronic apparatus includes a case 10 having an accessory installation region 11 recessed in a surface thereof to allow an accessory to be separably installed to the electronic apparatus, and a cover 20 separably fitted to the accessory installation region 11 to cover the accessory installation region 11.

The case 10 consists of a front case 10F and a rear case 10R, which are horizontally coupled to each other to define an external appearance of the electronic apparatus. The accessory installation region 11 is recessed in a rear surface of the rear case 10R.

A battery 30 to supply power to the electronic apparatus is separably seated in the accessory installation region 11. To this end, the accessory installation region 11 has a battery installation recess 12. As the cover 20 is fitted to the accessory installation region 11, the battery 30 seated in the battery installation recess 12 is covered and hidden by the cover 20.

To keep the cover 20 fitted to the accessory installation region 11, one end of the cover 20 is locked to a locking member 40 that is coupled to one end of the accessory installation region 11 in a forwardly or rearwardly movable manner. The cover 20 is selectively locked according to a position of the locking member 40. In the present exemplary embodiment, the cover 20 is locked if the locking member 40 is moved in a first direction, and is unlocked if the locking member 40 is moved in a second direction opposite to the first direction.

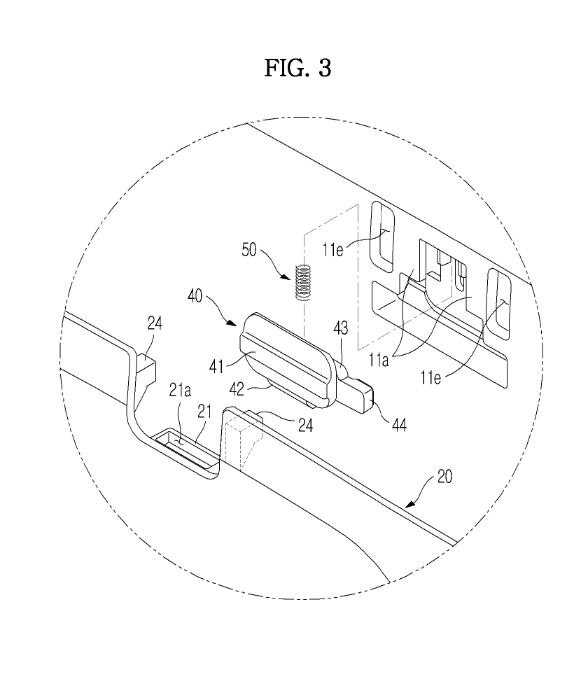

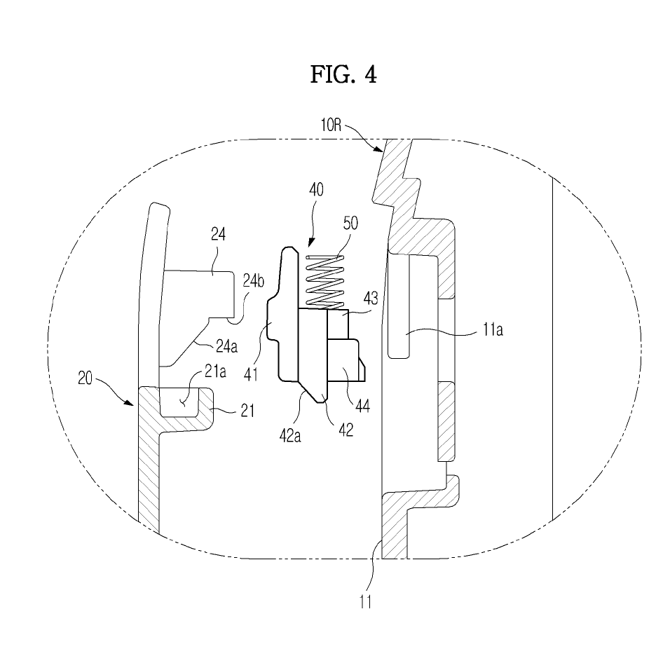

The locking member 40, as illustrated in FIGS. 3 and 4, includes a knob portion 41 to which an external force from a user is applied, and a first locking portion 42 that protrudes in the first direction and is adapted to be caught by the cover 20. The cover 20 includes a second locking portion 21 having a locking recess 21a into which the first locking portion 42 is inserted and caught. To keep the first locking portion 42 inserted in the second locking portion 21, an elastic member 50 is coupled to the locking member 40 to elastically support the locking member 40 in the first direction.

In addition, to movably couple the locking member 40 to the accessory installation region 11, the accessory installation region 11 is provided at one end thereof with a pair of first rails 11a and the locking member 40 is provided with a pair of second rails 43. The second rails 43 are spaced apart from the knob portion 41 such that the first rails 11a are interposed in a space between the second rails 43 and the knob portion 41. In this manner, the locking member 40 is movable on the first rails 11a.

The first locking portion 42 has a slope 42a inclined with respect to the cover 20, to allow the first locking portion 42 to be moved by the external force from the user transmitted via the cover 20 when the user covers the accessory installation region 11 with the cover 20.

Referring again to FIGS. 1 and 2, to couple the other end of the cover 20 to the accessory installation region 11, first retention portions 22 extend from opposite positions of the other end of the cover 20 and the accessory installation region 11 has first retention holes 11b. Each of the first retention portions 22 penetrates through the corresponding first retention hole 11b to thereby be supported at a position adjacent to the first retention hole 11b.

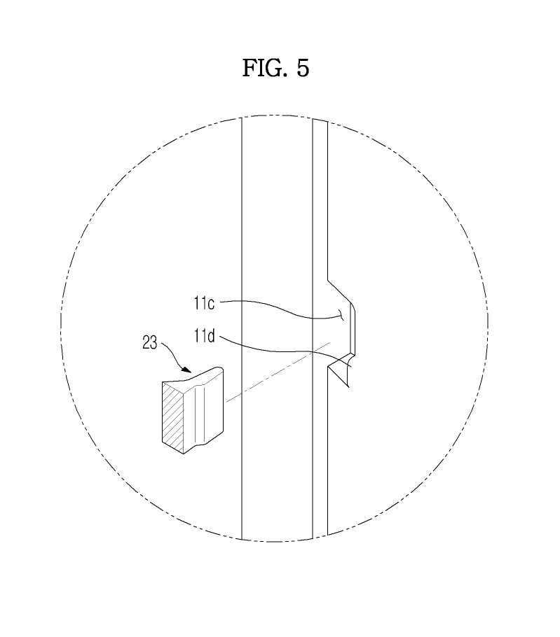

In addition, to couple both lateral ends of the cover 20 to the accessory installation region 11, second retention portions 23 extend from positions adjacent to both lateral ends of the cover 20 and the accessory installation region 11 has second retention holes 11c into which the second retention portions 23 are inserted. As illustrated in FIG. 5, each second retention hole 11c is formed with a third retention portion 11d. The third retention portion 11d protrudes inward of the second retention hole 11c to allow the second retention portion 23 to be selectively caught by the third retention portion 11d according to a position of the cover 20. In the present exemplary embodiment, the second retention portion 23 is temporarily elastically deformed by the external force applied to the cover 20, thereby being caught and supported by the third retention portion 11d. The second retention portion 23, second retention hole 11c and third retention portion 11d constitute a set, and a plurality of sets is spaced apart from one another on both lateral ends of the cover 20 and accessory installation region 11. In this manner, the cover 20 may be tightly coupled to the accessory installation region 11 with a uniform coupling strength throughout both lateral ends thereof.

With the above described configuration, once the first retention portions 22 are inserted into the first retention holes 11b to thereby be supported at positions adjacent to the respective first retention holes 11b, the cover 20 may be pivotally rotated about the first retention portions 22 upon receiving the external force from the user, so as to cover the accessory installation region 11.

In this case, the external force is transmitted from the second locking portion 21 of the cover 20 to the slope 42a of the first locking portion 42, causing the locking member 40 to be temporarily moved in the second direction. Then, as the locking member 40 is again moved in the first direction by elastic restoration force of the elastic member 50, the locking member 40 is inserted into the locking recess 21a. In addition, during pivotal rotation of the cover 20 to cover the accessory installation region 11, the second retention portions 23 provided at both lateral ends of the cover 20 are temporarily deformed and restored, thereby being caught and supported by the third retention portions 11d.

In the present exemplary embodiment, if the locking member 40 is moved in the second direction to unlock the cover 20, the cover 20 is moved to protrude outward from the accessory installation region 11. Specifically, the cover 20 is moved to protrude outward from the accessory installation region 11 simultaneously with unlocking thereof. This allows the user to more easily separate the cover 20 from the accessory installation region 11.

To this end, the locking member 40 is provided with a pair of first guides 44 and the cover 20 is provided with a pair of second guides 24. The first guides 44 of the locking member 40 are moved to penetrate through the accessory installation region 11, and the second guides 24 protrude onto a movement path of the first guides 44 so as to be caught by the first guides 44.

In the present exemplary embodiment, the first guides 44 integrally extend from the respective second rails 43. Therefore, to allow the second guides 24 to be placed on the movement path of the first guides 44, one end of the cover 20 is formed with a through-hole 25 to expose the knob portion 41 of the locking member 40. The accessory installation region 11 has through-holes 11e through which the second guides 24 are inserted.

Each of the second guides 24 is provided at a surface thereof facing the corresponding first guide 44 with a first guide surface 24a and a second guide surface 24b. The first guide surface 24a is inclined with respect to the movement path of the first guide 44 to allow the cover 20 to protrude outward from the accessory installation region 11. The second guide surface 24b is configured to be caught by the first guide 44 to allow the cover 20 to be moved along with the locking member 40.

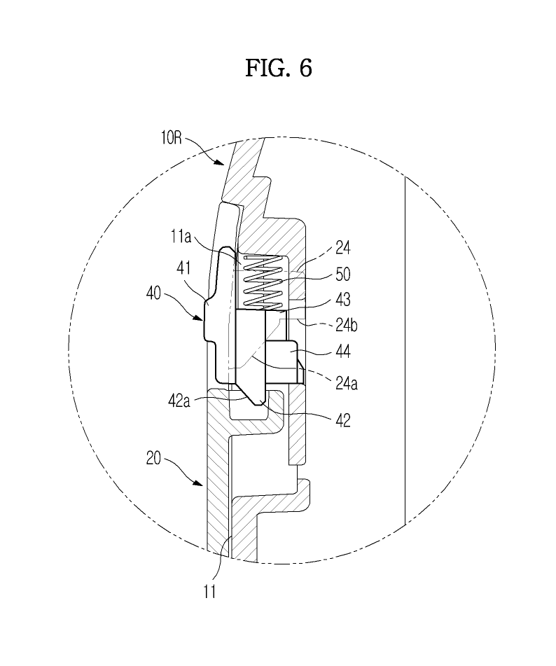

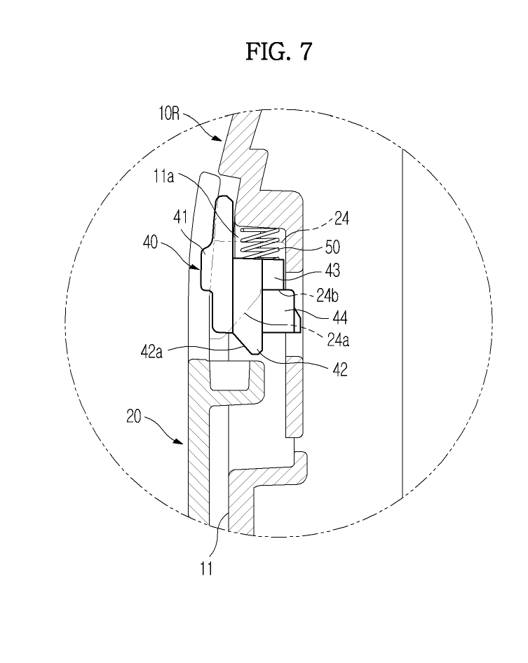

With this configuration, as illustrated in FIG. 6, if the knob portion 41 of the locking member 40 is forced to move the locking member 40 in the second direction in a state wherein the cover 20 is locked by the locking member 40, the first guide surface 24a in the form of an inclined surface acts to change the acting direction of a part of the force used to move the locking member 40 into a direction perpendicular to the second direction. In this manner, as a part of the force is transmitted to the cover 20 in the direction perpendicular to the second direction by the second guide 24, the cover 20 is moved to protrude outward from the accessory installation region 11 as illustrated in FIG. 7.

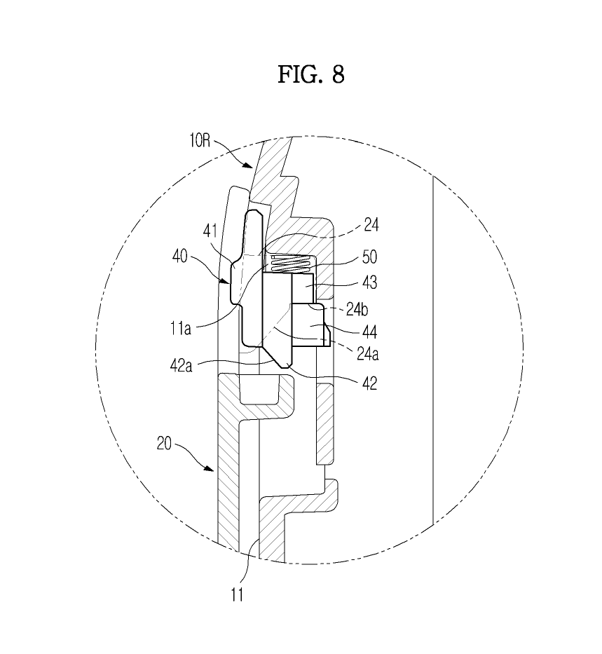

Then, if the locking member 40 is further moved, the first guide 44 is caught by the second guide surface 24b, thus allowing a part of the force applied to move the locking member 40 to be transmitted to the cover 20 via the second guide surface 24b. Thereby, the cover 20, as illustrated in FIG. 8, is moved in the second direction by a predetermined distance along with the locking member 40. That is, as the locking member 40 is moved in the second direction, the cover 20 is first moved to protrude outward from the accessory installation region 11 and thereafter, is moved in the second direction by a predetermined distance. In this case, the second retention portions 23 caught by the third retention portions 11 d are temporarily elastically deformed and separated from the third retention portions 11 d as the cover 20 is moved to protrude outward from the accessory installation region 11. After the cover 20 is moved in the second direction along with the locking member 40, the cover 20 is kept at a position protruding from the accessory installation region 11 and thus, the second retention portions 23 are completely separated from the third retention portions 11d to prevent the cover 20 from being again moved in the first direction. In this manner, the cover 20 is kept at a position moved in the second direction before an additional external force is applied to the cover 20.

When the cover 20 is first moved to protrude outward from the accessory installation region 11 and then, is moved in the second direction, one end of the cover 20 is positioned to allow the user to easily apply external force thereto and thus, the user may easily separate the cover 20 from the accessory installation region 11.

Although the above described exemplary embodiment illustrates the battery 30 as being separably seated in the accessory installation region 11, it is not limited thereto, and other various accessories, such as a memory card, etc., may be separably installed in the accessory installation region 11.

As is apparent from the above description, in an electronic apparatus according to an exemplary embodiment, a cover is moved to protrude from an accessory installation region as a locking member is moved to unlock the cover. This enables more easy separation of the cover from the accessory installation region.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. An electronic apparatus comprising:
a case comprising an accessory installation region in a surface of the case, in which an accessory is separably installed;
a cover separably coupled to the accessory installation region to cover the accessory installation region; and
a locking member mounted in the accessory installation region and adapted to be moved in a first direction and be caught by one end of the cover,
wherein the one end of the cover is moved to protrude outward from the accessory installation region as the locking member is moved in a second direction opposite to the first direction.

2. The electronic apparatus according to claim 1, wherein the cover protruding from the accessory installation region is moved in the second direction along with the locking member as the locking member is further moved in the second direction.

3. The electronic apparatus according to claim 1, further comprising:
a first guide provided at the locking member; and
a second guide provided at the cover and placed on a movement path of the first guide,
wherein the second guide comprises a first guide surface inclined with respect to the movement path of the first guide.

4. The electronic apparatus according to claim 3, wherein the second guide further comprises a second guide surface to be caught by the first guide to allow the cover to be moved in the second direction along with the locking member.

5. The electronic apparatus according to claim 1, wherein:
the accessory installation region is provided at one end with a pair of first rails on which the locking member is movably mounted: and
the locking member comprises a knob portion to which external force is applied, and a pair of second rails spaced apart from the knob portion and movably mounted on the first rails.

6. The electronic apparatus according to claim 1, wherein:
the locking member comprises a first locking portion extending in the first direction and adapted to be caught by the cover; and
the cover comprises a second locking portion comprising a locking recess into which the first locking portion is inserted and caught.

7. The electronic apparatus according to claim 1, further comprising an elastic member to elastically urge the locking member in the second direction opposite to the first direction.

8. The electronic apparatus according to claim 1, wherein:
the cover comprises a first retention portion protruding from another end of the cover and adapted to be caught by the accessory installation region; and
the accessory installation region comprises a first retention hole by which the first retention portion is caught and supported.

9. The electronic apparatus according to claim 8, wherein:
the cover further comprises a second retention portion provided at a position adjacent to either lateral ends of the cover and adapted to be caught by the accessory installation region; and
the accessory installation region further comprises a second retention hole by which the second retention portion is caught and supported, and a third retention portion protruding inward of the second retention hole to allow the second retention portion to be selectively caught by the third retention portion according to a position of the cover.

10. The electronic apparatus according to claim 1, further comprising a battery,
wherein the accessory installation region comprises a battery installation recess comprising a shape corresponding to the battery to allow the battery to be separably seated therein.

11. An electronic apparatus comprising:
a case comprising an accessory installation region in a surface of the case, in which an accessory is separably installed;
a cover separably coupled to the accessory installation region to cover the accessory installation region;
a locking member mounted in the accessory installation region adapted to be moved in a first direction and be caught by one end of the cover;
a first guide provided at the locking member; and
a second guide provided at the cover and placed on a movement path of the first guide of the locking member that is adapted to be moved in a second direction opposite to the first direction,
wherein the second guide comprises a first guide surface inclined with respect to the movement path of the first guide.

12. The electronic apparatus according to claim 11, wherein the second guide further comprises a second guide surface to be caught by the first guide to allow the cover to be moved in the second direction along with the locking member.
